(19) United States
(12) Patent Application Publication
(10) Pub. No.: US 2005/0092360 A1
(43) Pub. Date: May 5, 2005

(54) Optical concentrator for solar cell electrical power generation

(76) Inventor: Roy Clark, Thousand Oaks, CA (US)

Correspondence Address: FELIX L. FISCHER, ATTORNEY AT LAW, 1607 MISSION DRIVE, SUITE 204, SOLVANG, CA, 93463, US

(21) Appl. No.: 10/699,480

(22) Filed: Oct. 30, 2003

(51) Int. Cl. H01L 31/00

(52) U.S. Cl. 136/259; 136/246

(57) ABSTRACT

An optical concentrator for a power generation solar cell incorporates a Fresnel lens element and a secondary non-imaging concentrating element mounted intermediate the Fresnel lens and the solar cell. The Fresnel lens focuses sunlight over the solar cell active surface when the concentrator is aligned with the sun. The secondary non-imaging concentrating element redirects sunlight from the lens including edge rays onto the solar cell surface within the periphery of the active area of the cell when the concentrator is misaligned by no more than a predetermined angle.

### FIELD OF THE INVENTION

This invention relates generally to the field of solar cells and, more particularly, to a combination of a Fresnel lens with a non-imaging optical concentrator to accommodate solar tracking system misalignment for reduced solar cell area and increased tolerance for tracking system angular error.

### BACKGROUND OF THE INVENTION

The major cost driver in electrical power generation using solar cells is the cost of the cells themselves. In order to reduce this cost, a solar concentration system can be employed that places a higher solar light intensity onto a smaller solar array. Prior art includes reflective solar dishes and concentrators based on Fresnel lenses of various types. However, the use of such concentrators requires a solar tracking system that keeps the collection optics aligned with the sun as it moves across the sky. The cost of such a tracking system is significant and may negate the cost advantage of using a concentrator to increase illumination intensity and reduce the number of solar cells required to generate electricity. One of the major cost elements in a solar tracking system is the accuracy with which the concentrated sunlight can be placed on a small group of solar cells. Prior art, using for example the linear curved Fresnel lens design revealed in U.S. Pat. No. 4,069,812, requires that the array of solar cells be larger than the size of the concentrated solar illumination in order to compensate for inaccuracies in the tracking mechanism. Typically, the size of the solar array is increased by a factor of 2 to 4 just to compensate for the inaccuracies in the tracking system.

The basic Fresnel lens was introduced by Augustine Fresnel in 1822 and used initially for lighthouses. Instead of fabricating a very large, thick lens 2, the Fresnel lens 4 is made from thin sections with varying sizes and slopes. This is illustrated in FIG. 1. If the sections are linear in shape, a cylindrical lens is produced that brings the light to a line focus. If the sections are circular, a spherical lens is produced that brings the light to a point focus. A major improvement in the art of making large linear Fresnel lenses was revealed by O'Neill (U.S. Pat. No. 4,069,812). Instead of making the lens flat, the lens is curved and the additional optical magnification power gained from the curved surface leads to improved optical throughput. The curved Fresnel lens 6 is illustrated in FIG. 2 with the resulting convergence angle 8 for the edges rays projected by the lens. Subsequent patents reveal the art of improved solar cell mounting (U.S. Pat. No. 5,498,297) improved radiation protection (U.S. Pat. No. 5,505,789), improved color mixing (U.S. Pat. No. 6,031,179) and means of deployment of such lenses for space power applications (U.S. Pat. Nos. 6,075,200 and 6,111,190). However, none of this prior art reveals the use of a secondary concentrator to reduce the misalignment sensitivity.

Another means of improving the efficiency of a Fresnel lens is revealed in U.S. Pat. No. 4,337,759. In this case a second layer of a transparent (plastic) material of a different refractive index is laminated to the first. Total internal reflection (TIR) at the specially contoured interface between the two materials leads to a significant improvement in optical throughput. In this invention however, the device was used as an illuminator to expand and collimate the light source instead of as a solar concentrator. Although a tracking means was included, this was aimed at a general target, not at the sun. Subsequent patents (U.S. Pat. Nos. 5,404,869 and 5,577,492) reveal improved devices using curved facets at the internally reflecting interface. U.S. Pat. No. 5,577,493 reveals the use of an additional conventional lens to improve illumination uniformity. U.S. Pat. Nos. 5,613,769 and 5,676,453 reveal an essentially cylindrical lens design to be used for example in tubular (fluorescent) lighting fixtures and U.S. Pat. No. 5,806,955 reveals an arrangement for using a TIR lens for optical display backlighting.

The art of designing non-imaging optical elements is well known and as shown for example in Welford and Winston [Welford, W. T. & R. Winston, High Collection Nonimaging Optics, Academic Press, San Diego, Calif., 1989]. Although there are many different designs of optical concentrator, they can be classified into four principal types. The first is the compound parabolic concentrator. The second is the hyperbolic or ‘trumpet’ concentrator. The third type consists of concentrators designed using the edge ray principle as described for example by Gordon and Ries [Gordon, J. M. & H. Ries, Applied Optics 32(13) 2243-2251 (1993), Tailored edge ray concentrators as ideal second stages for Fresnel reflectors], Ong et al [Ong, P. T.; J. M. Gordon & A. Rabl, Applied Optics 34(34) 7877-7887 (1993), Tailoring lighting reflectors to prescribed illuminance distributions: compact partial involute designs; Ong, P. T.; J. M. Gordon & A. Rabl, Applied Optics 35(22) 4361-4371 (1996), Tailored edge ray designs for illumination with tubular sources; Ong, P. T.; J. M. Gordon, A. Rabl & W. Cai, Optical Engineering 34(6) 1726-1737 (1995), Tailored edge ray designs for uniform illumination of distant targets], Rabl [Rabl, A., Applied Optics 33(7) 1248-1259 (1994), Edge ray method for analysis of radiation transfer among specular reflectors] and Rabl and Gordon [Rabl, A. & J. M. Gordon, Applied Optics 33(25) 6012-6021 (1994), Reflector design for illumination with extended sources: the basic solutions]. The fourth type are all dielectric concentrators in which total internal reflection is used to concentrate the light. Such devices were discussed by Friedman and Gordon [Friedman, R. P. & J. M. Gordon, Applied Optics 35(34) 6684-6691 (1996), Optical designs for ultrahigh flux IR and solar energy collection: monolithic dielectric tailored edge ray concentrators]. These design types are illustrated in FIGS. 3a, 3b, 3c, 3d, 3e, 3f and 3g.

### SUMMARY OF THE INVENTION

An optical concentrator for a power generation solar cell according to the present invention employs a Fresnel lens element mounted over a solar cell to focus sunlight over the solar cell surface when the concentrator is aligned with the sun and a secondary non-imaging concentrating element mounted intermediate the Fresnel lens and the solar cell to redirect sunlight from the lens including edge rays onto the solar cell surface within the periphery of the active area of the cell when the concentrator is misaligned by a predetermined angle.

### BRIEF DESCRIPTION OF THE DRAWINGS

These and other features and advantages of the present invention will be better understood by reference to the following detailed description when considered in connection with the accompanying drawings wherein:

FIG. 1 is a depiction of a basic Fresnel lens as compared to the configuration of a normal curved lens;

FIG. 2 is a depiction of a curved Fresnel lens;

FIG. 3a is an exemplary parabolic concentrator applicable to the present invention;

FIG. 3b is an exemplary hyperbolic concentrator applicable to the present invention;

FIG. 3c is an example of a far edge diverging concentrator applicable to the present invention;

FIG. 3d is an example of a near edge diverging concentrator applicable to the present invention;

FIG. 3e is an example of a far edge converging concentrator applicable to the present invention;

FIG. 3f is an example of a near edge converging concentrator applicable to the present invention;

FIG. 3g is an example of a dielectric concentrator applicable to the present invention;

FIGS. 3h and 3i are generalized linearizations of the curved surfaces of the concentrators in FIGS. 3a through 3f,

FIG. 4 is an exemplary embodiment of the present invention employing a V-trough concentrator;

FIG. 5 is a graphical depiction of an exemplary means for determining the contour of the V-trough concentrator of FIG. 4; and,

FIG. 6 is a graphical depiction of the V-trough concentrator and the divergence angle of the Fresnel lens;

FIG. 7 is a plot of the calculated hyperbola and best line fit for a V-trough for the exemplary embodiment of the invention; and

FIG. 8 is a schematic representation of a solar tracking system employing the present invention.

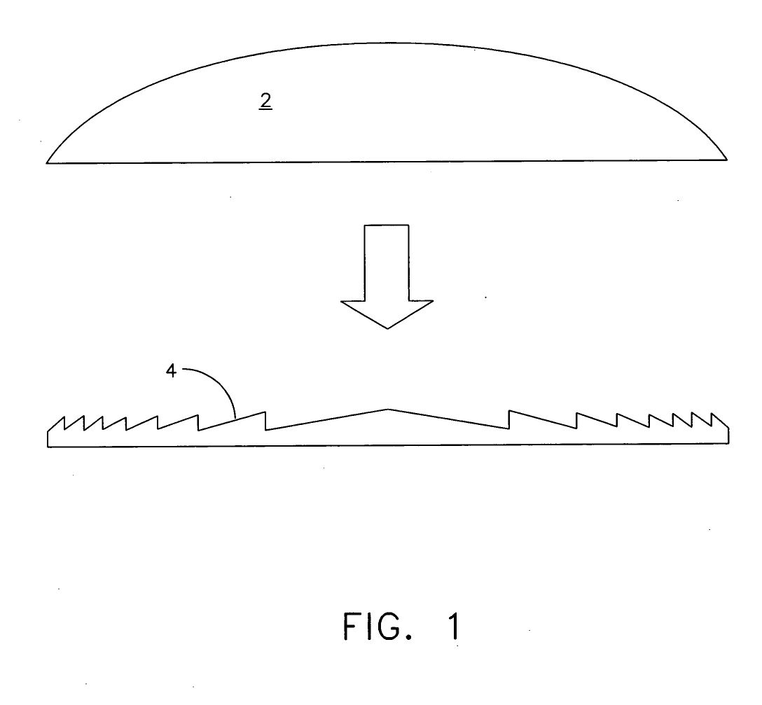

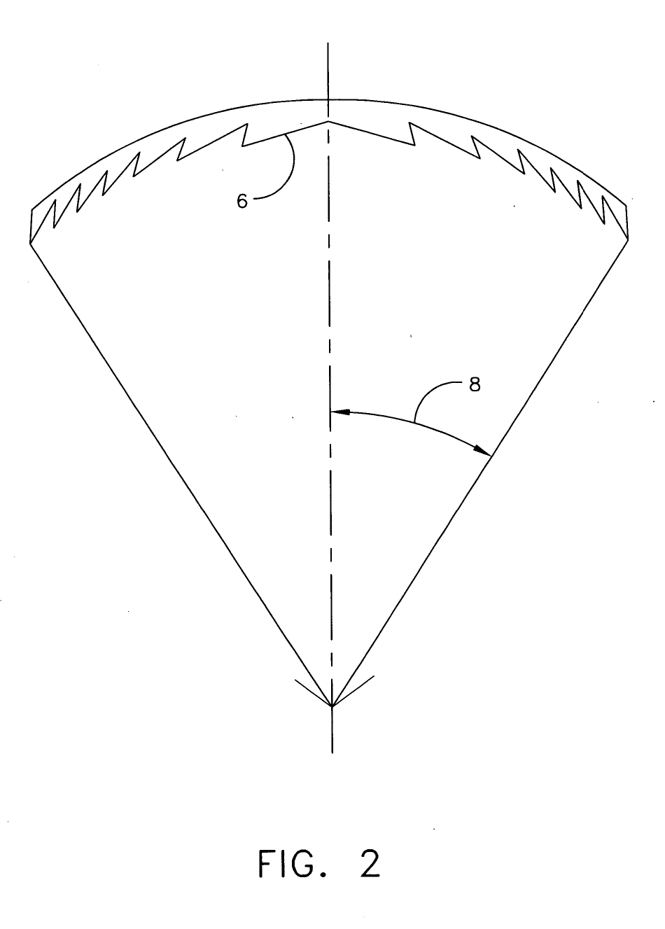

### DETAILED DESCRIPTION OF THE INVENTION

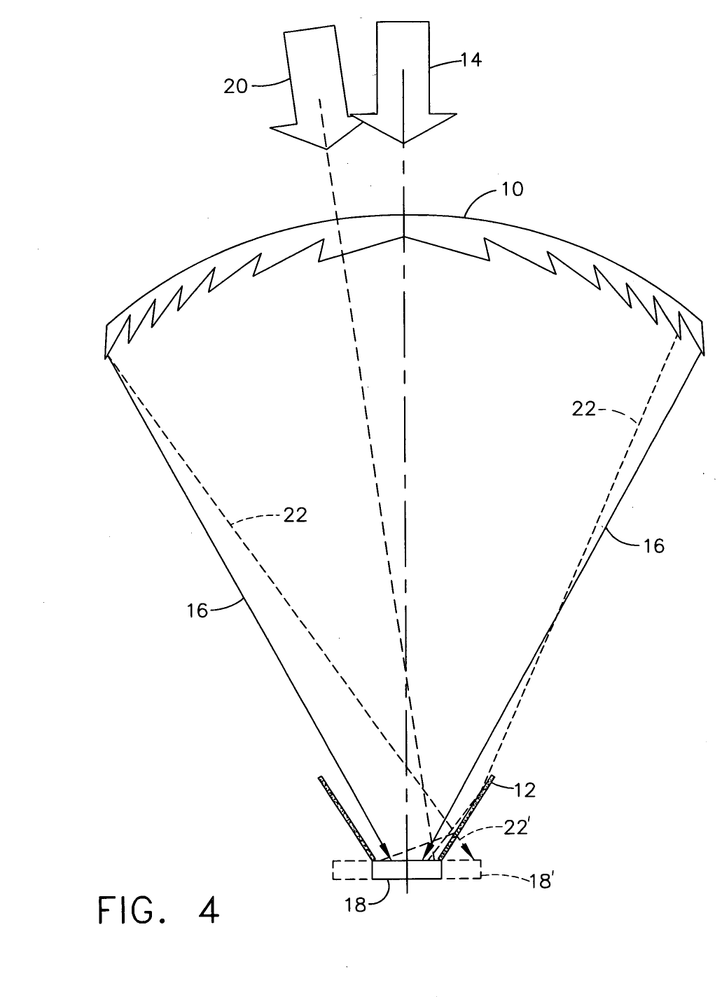

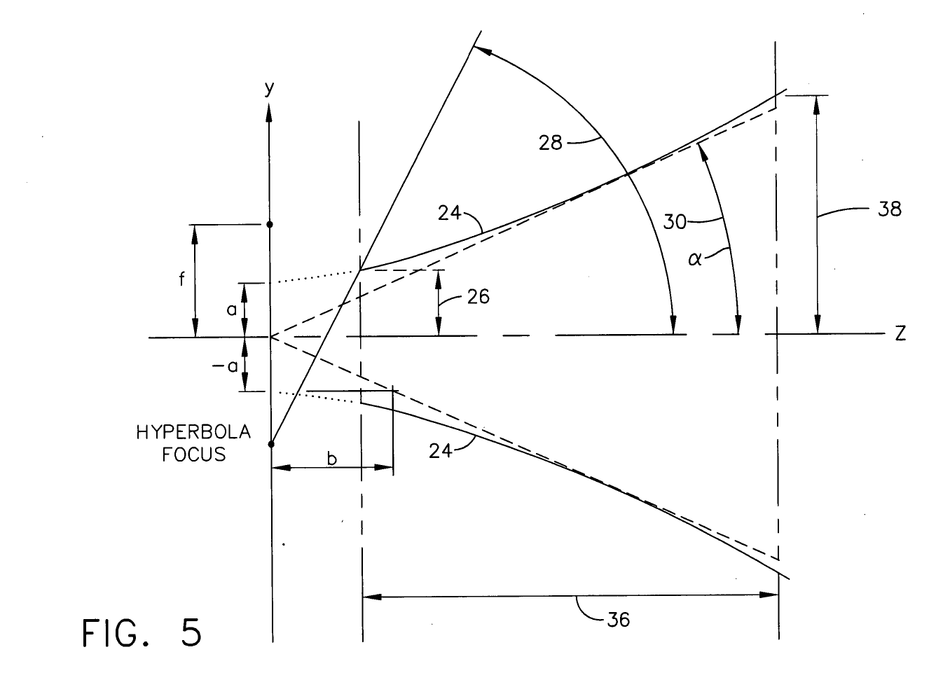

Referring to the drawings, an embodiment of the present invention is revealed in FIG. 4. A linear Fresnel concentrator, as disclosed for example in U.S. Pat. No. 4,069,812, having a lens 10 is structurally supported at a predefined distance from a secondary concentrator 12. When the tracking system is fully aligned, sunlight from the direction indicated by the arrow 14 is concentrated by the curved Fresnel lens. As demonstrated by the edge rays of the concentrated light shown as path 16, all light impinging on the lens is directly incident on the solar cell 18 within the periphery of the active surface area for the cell. While a single solar cell is referred to herein, the present invention is also employed with multiple cells arranged to accommodate an extended linear Fresnel lens. When the tracking system is misaligned, sunlight now enters the lens from the direction indicated by the arrow 20. The edge rays of the concentrated light now follow the directions shown by path 22. The light which would normally miss the solar cell active surface area (represented by lines 22′) without oversizing the cell (shown in phantom as 18′ as in conventional systems employing solely a Fresnel lens as the concentrator) is now reflected by the secondary concentrator and redirected onto the active area of the solar cell. For the embodiment shown, the concentrator is a simple V-trough whose contour is derived from a straight line fit to an optimized section of a hyperbolic concentrator. This approach is illustrated in FIG. 5. Such a design approach is described, for example, in Welford and Winston (previously referenced).

As an example for a 1 meter Fresnel lens having a 1 meter focal point, the hyperbolic surface 24 is designed based on a desired exit aperture half width 26 which is determined by the width of the solar cell, which may also include a cover plate or other optically transmissive means for protecting the cell surface from contamination. This optically transmissive element may also incorporate additional means of changing the divergence angle of the exit beam from the secondary concentrator. A typical value for this half width is 1 cm.

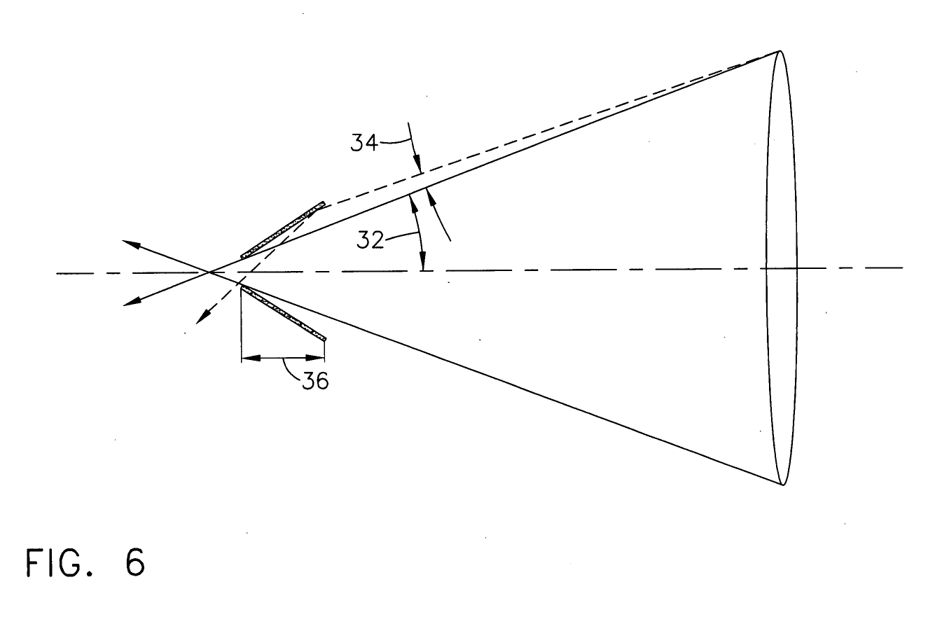

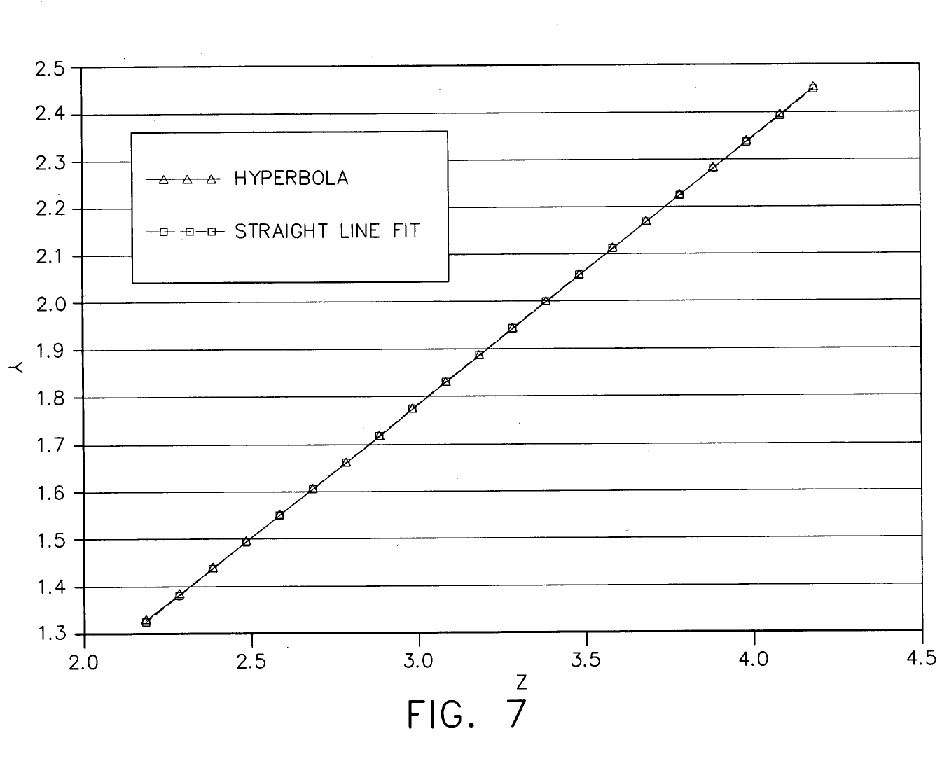

An exit angle, θ, 28 is selected to illuminate the solar cell without incurring excessive reflective losses due to Fresnel reflections from the internal semiconductor surfaces of the cell. A typical value is 40 degrees. The distance between the exit aperture and the primary Fresnel lens is selected so that the cell is illuminated by direct light that is not reflected by the secondary concentrator when the optical tracking system is optimally pointed at the sun. The asymptote angle, α, 30 of the hyperbola is selected to be slightly larger than the divergence angle 32 of the primary Fresnel lens to capture the edge rays from the lens at the maximum angular error for the optical tracking system, as best seen in FIG. 6. For the exemplary 1 meter Fresnel lens with a 1 meter focal point the divergence angle is approximately 27 degrees and a typical value for the asymptote angle is 30 degrees thereby providing a misalignment angle 34 of approximately 3 degrees. Using the defined values of the exit angle, the asymptote angle and the exit aperture half width, the hyperbola parameters “a”, “b” and “f” can be calculated. Since the hyperbola parameter “a” must be less than the value of the exit aperture, a simple iterative procedure can be used. Z is calculated from tan(θ)=(y+f)/z with y fixed to the desired exit aperture size. “y” is calculated from this value of “z” using the hyperbola equation y²/a²−z²/b²⁼¹. “f” and “b” are expressed in terms of “a” using tan(a)=a/b and f²=a²+b². The variable parameter “a” is then adjusted until the desired value of y is reached.

The length 36 of the secondary concentrator that defines the entrance aperture half width 38, in conjunction with the selected asymptote angle discussed above, is determined from the maximum tracking error to be corrected. The best straight line fit to the hyperbola length determined based on the selected iterative parameters discussed above determines the practical secondary concentrator shape.

The calculations for the exemplary hyperbola and resulting V-trough discussed above are shown in Table 1.

TABLE 1

| | | |
|---|---|---|
| Alpha | 30 | |
| Theta | 40 | |
| Exit Aperture Half | 1 | |
| Width | | |
| Tan(Alpha) | 0.57735 | |
| Tan(Theta) | 0.8391 | |
| a | 0.41635 | |
| b | 0.721139 | |
| f | 0.8327 | f = sqrt(a\hat{ }2 + b\hat{ }2) |
| z | 2.184127 | z = (0.5 + f)/tan(theta) |
| y | 1.327962 | y = sqrt(a\hat{ }2 * (1 + z\hat{ }2/b\hat{ }2)) |
| z Increment | 0.1 | |

| | | Hyperbola | St Line Fit | | |
|---|---|---|---|---|---|
| z | 2.184127 | 1.327962 | 1.324414 | slope | 0.562181 |
| | 2.284127 | 1.382905 | 1.380632 | Intercept | 0.09654 |
| | 2.384127 | 1.438066 | 1.43685 | | |
| | 2.484127 | 1.493422 | 1.493068 | | |
| | 2.584127 | 1.548952 | 1.549286 | | |
| | 2.684127 | 1.604637 | 1.605504 | | |
| | 2.784127 | 1.660462 | 1.661722 | | |
| | 2.884127 | 1.716414 | 1.71794 | | |
| | 2.984127 | 1.77248 | 1.774158 | | |
| | 3.084127 | 1.82865 | 1.830376 | | |
| | 3.184127 | 1.884914 | 1.886594 | | |
| | 3.284127 | 1.941265 | 1.942812 | | |
| | 3.384127 | 1.997695 | 1.99903 | | |
| | 3.484127 | 2.054197 | 2.055248 | | |
| | 3.584127 | 2.110767 | 2.111466 | | |
| | 3.684127 | 2.167397 | 2.167684 | | |
| | 3.784127 | 2.224085 | 2.223903 | | |
| | 3.884127 | 2.280825 | 2.280121 | | |
| | 3.984127 | 2.337613 | 2.336339 | | |
| | 4.084127 | 2.394447 | 2.392557 | | |
| | 4.184127 | 2.451323 | 2.448775 | | |

The resulting straight line fit for the V-trough is shown in FIG. 7 wherein the ideal hyperbola shape is shown with triangular indices and the straight line fit is shown with square indicies.

This design approach may also be refined using more advanced ray-tracing techniques found in commercial illumination software packages such as Light Tools, Optical Research Associates, Pasadena, Calif. and ASAP, Breault Research Organization, Tucson, Ariz.

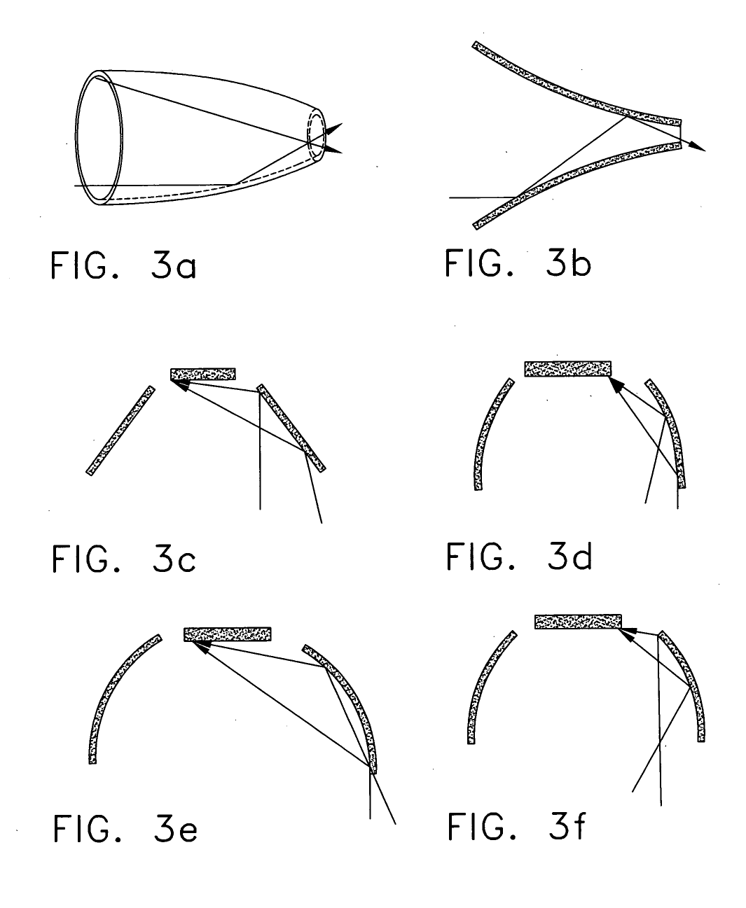

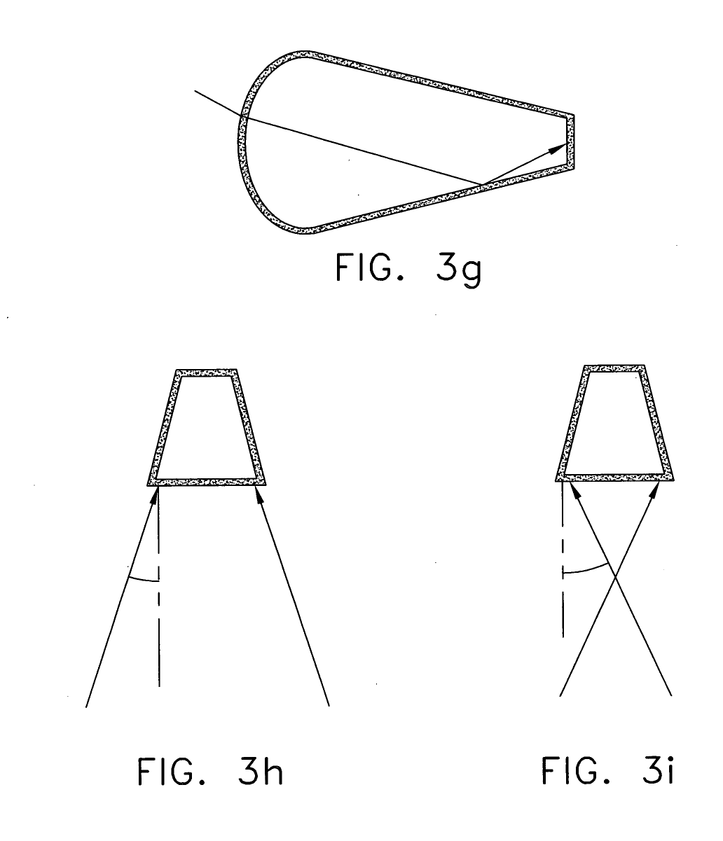

The present invention is not limited to a V-trough concentrator. Many other types of concentrator such as the parabolic or true hyperbolic concentrator, hollow concentrators derived from edge ray design principles and monolithic dielectric concentrators are employed in alternative embodiments of this invention. Although the design method is different and in some cases more complex than the embodiment shown in the drawings, the net result is the same: a secondary concentrator with a defined acceptance angle and a surface contour that may be simplified, if desired, to a best fit straight line through the optimum curve. The choice of straight line or curve is a practical one based on system cost and efficiency considerations. In all cases, the acceptance angle of the concentrator can be arranged to accommodate alignment errors in the solar tracking system. FIGS. 3h and 3i demonstrate the generalized best fit straight line embodiment conceptually derived for an arbitrary one of the concentrators of FIGS. 3a-3f.

Further, in each case, an entrance aperture for the secondary concentrator defined by the length of the secondary concentrator and a primary reflection angle associated with the geometry, corresponding to the asymptote angle for the hyperbola shown in the embodiment described in detail herein, is defined to accommodate a predetermined misalignment angle for the tracking system with exit angle and exit aperture defined to accommodate the particular cell size and configuration. Furthermore, although the for the embodiment of the invention disclosed, a linear Fresnel lens is employed, a circular Fresnel lens is employed in alternative embodiments. In this embodiment, a cone is substituted for the V-trough using the same design principle and having a section view across a diameter identical to FIG. 4. Many other more complex surfaces may be derived using the design principles known to those skilled in the art of making optical concentrators. Instead of a circular Fresnel lens, two orthogonal cylindrical Fresnel lenses may be used. The Fresnel lenses may be of a conventional design, curved design, or contain TIR elements.

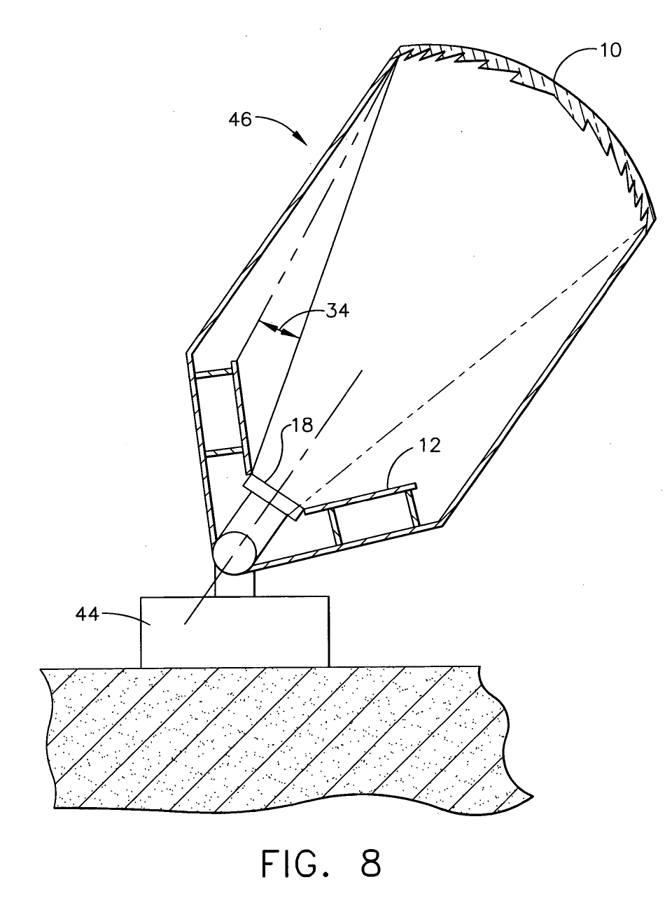

Implemented at the system level as shown schematically (with the lens at much reduced scale) in FIG. 8, the tracking system 44 supports the solar cell 18 and the concentrator system 46 employing the Fresnel lens 10 and secondary concentrator 12. The predetermined misalignment angle for the tracking system is accommodated by the secondary concentrator to allow practical constraints on the alignment accuracy of the system resulting in lower cost and complexity.

Having now described the invention in detail as required by the patent statutes, those skilled in the art will recognize modifications and substitutions to the specific embodiments disclosed herein. Such modifications are within the scope and intent of the present invention as defined in the following claims.

1-10. (canceled)

11. A method of playing a historical war game with flat soldiers for at least two players, representing opposing sides, which is conducted on a smooth flat surface, bounded by a line representing the boundary of the battlefield, with a set of flats game pieces (units) which represent figures of warriors, war animals, standards, military equipment and armaments, fortifications, and models of projectiles, corresponding to a certain historical period, a ruler, a support for imitation of shooting, topographical maps and standard playing dice, said method of controlled with rules for administering a battle and rules for evaluation of military actions, which take into account equipment, weapons and configuration of detachments, intervals of unit displacement, radii of damage delivery by projectiles, efficiency of attack and defense for different types of units, fitting with a certain historical period, which contains the following steps:
a. agreement between players upon time and place of a battle, composition of the armies, conditions to end the battle and end the war, definition of the purpose of the battle and determination of the initial positioning of detachments with a help of included topographical maps;
b. marking a line on said smooth flat surface, that signifies the said boundary of the battlefield;
c. announcement of the disposition of each detachment by the opposing players;
d. placement of said game pieces by said opposing players on said smooth flat surface within said boundary of the battlefield, according to the disposition of their detachments, while those detachments that are considered as reserve are placed outside said boundary of the battlefield;
e. determination of the side making the first move with draw of standard playing die;
f. conducting moves one side after another, each move consisting of:
announcement of all military actions, such as shooting and movement, that is to be conducted during this turn;
shooting by placing said models of projectiles onto said support for imitation of shooting, placing said support on top of the units regarded to be shooting, and making a shot with a click of a finger, shooting being conducted according to said rules for administering a battle, accounting for the fact that if the figure of a unit gets within the damage zone of a given type of projectile, that unit is damaged and is dismissed from the battlefield;
movement of the chosen detachments within the limits of said intervals of unit displacements, according to said rules for administering a battle;
hand-to-hand combat, if it is plausible for a given historical period and if, as a result of displacement, units of a detachment came into direct contact with units of an opposing detachment, according to said rules for administering a battle;
evaluation of military action depending on relational losses of each detachment after each side had a right of turn, counted at the time and in a manner described in said rules for evaluation of military actions;
g. agreement to conduct negotiations to end all military actions if one side has lost part of its army, agreed on beforehand, in this case the side which lost more units is considered to be the losing side.
h. end of war as a collection of battles if one of the sides has lost its capital, or a part of territory, or part of its army, as agreed for at the beginning of the game, in this case said side is considered to be the losing side.

12. The method of playing a historical war game, as claimed in claim 11, wherein said rules for administering a battle control:
a. order of shooting;
b. order of detachment movement;
c. rules for hand-to-hand combat;
d. rules for military action at or near said fortifications;
e. conditions for capturing opposing player's units;
f. rules for entry of detachments currently in reserve.

13. The method of playing a historical war game, as claimed in claim 12, wherein said order of shooting for a historical period of second half of fourteenth-first quarter of fifteenth century is controlled by the following rules:
a. if at the beginning of shooting the number of archers on the battlefield is greater than 10, the number of shots available to players holding the right of turn is fifty percents of the number of archers, but no less than ten shots;
b. if the total number of archers is smaller than or equal to ten, the number of available shots is the total number of archers on the battlefield;
c. bowmen can shoot every turn, crossbowmen can shoot every other turn;
d. at the beginning of a battle, a bowman has ten arrows in his possession, a crossbowman has five arrows;
e. an infantry archer has a right of shot if he has no more than one row of infantrymen of the same army in front of him, while a cavalry archer has a right of shot if no more than two rows of infantrymen or one row of the same army cavalrymen in front of him, otherwise an archer has no shot during a current turn.

14. The method of playing a historical war game, as claimed in claim 12, wherein said order of detachment movement for a historical period of second half of fourteenth-first quarter of fifteenth century is controlled by the following rules:
a. each side can move no more than half its detachments per turn;
b. each detachment can move in any direction, provided it does not split into smaller detachments;
c. during movement, no part of a unit's figure can be put on top of another unit's figure.

15. The method of playing a historical war game, as claimed in claim 12 wherein said rules for hand-to-hand combat account for efficiency of attack and defense of units participating and for a historical period of second half of fourteenth-first quarter of fifteenth century, are controlled by the following rules:
a. hand-to-hand combat between opposing detachments consists of local clashes between two or several opposing units, provided that any given unit can attack only one opposing unit;
b. a clash where several units attack one opposing unit is allowed only if the sum of their efficiencies of attack is no greater than twice the efficiency of defense for the defending unit;
d. the number of points on the faces of thrown dice defines immediate efficiency of units participating in a clash, wherein the proportions between the number of dice for attackers and a defender and between the sum of efficiencies of attack for the attackers and the efficiency of defense for the defender are equivalent.

16. The method of playing a historical war game, as claimed in claim 12, wherein said rules for administering a battle at or near said fortifications for a historical period of second half of fourteenth-first quarter of fifteenth century, are controlled by the following rules:
a. a catapult can shoot every third turn;
b. if a stone projectile hits a fortification, any block covered even partly by the projectile is destroyed, creating a breach;
c. a flaming projectile does no damage to a fortification;
d. units of the side storming a fortification can enter the fortification if the figure of a unit can fully fit through a breach in the fortification;
e. figures of units defending a fortification on the wall are covered by it up to, but no further than the chest;
f. The substitution of damaged units on the walls with fresh units is conducted during the player's next turn;
g. each siege ladder is carried by four infantrymen;
h. a battering ram used to destroy a fortification's gates is moved by 6 infantrymen;
i. in order to destroy the fortification gates at least two blows must be delivered to them with a ram, wherein each blow consist of two moves: the blow itself and the consequent backing up of the ram.

17. The method of playing a historical war game, as claimed in claim 11, wherein said rules for evaluation of military actions are based on the evaluation of losses suffered by each side during shooting or hand-to-hand combat.

18. The method of playing a historical war game, as claimed in claim 17, wherein said evaluation of losses suffered by each side during shooting or hand-to-hand combat for a historical period of second half of fourteenth-first quarter of fifteenth century, is controlled by the following rules:
a. loss of units dismissed from the battlefield is quantified through penalty points and depends on the type of unit;
b. success of military action is determined through a coefficient of loss W for every detachment, such that W=B/C, where B is the sum of the penalty points, corresponding to detachment's losses, and C is the sum of said efficiencies of defense for every unit in the detachment, either determined at the beginning of the game or recalculated after the previous military action's evaluation;
c. outcome of losses suffered, depending on the value of said coefficients of loss W of that detachment, can be one of the following:
detachment surrenders;
detachment flees the battlefield;
detachment retreats the distance one and a half times that of the largest possible move of its speediest unit;
detachment retreats the distance of the largest possible move of its speediest unit;
detachment continues the battle in the same position.

19. The method of playing a historical war game, as claimed in claim 12, wherein said rules for entry of detachments currently in reserve for a historical period of second half of fourteenth-first quarter of fifteenth century, are controlled by the following rules:
a players can conduct entry of reserve units during any turn;
b. entry of reserve units into the area next to the said boundary of the battlefield requires one turn;
c. reserve units currently located beyond the said boundary of the battlefield suffer no damage from opposing projectiles.

20. The method of playing a historical war game, as claimed in claim 12, wherein said conditions for capturing the opposing side's units, trophies for a historical period of the second half of fourteenth-first quarter of fifteenth century is controlled by the following rules:
a In a clash where several units attack one opposing player's unit and the sum of their efficiencies of attack is greater or equal to three times the efficiency of defense of the defending unit, that unit is considered to be captured.
b. If the distance between the attacked unit and the nearest unit of its own army is equal to 2 inches or less, that unit cannot be.
c. Units of the player's army that participated in the capturing of the opposing player's unit cannot capture another opposing player's unit during the same turn.
d. The entire detachment can be captured depending on the particular value of said coefficient of loss W of that detachment.
